(19) United States
(12) Patent Application Publication
(10) Pub. No.: US 2013/0334555 A1
(43) Pub. Date: Dec. 19, 2013

(54) OPTOELECTRONIC DEVICE AND METHOD FOR MANUFACTURING THE SAME

(71) Applicant: Epistar Corporation, Hsinchu (TW)

(72) Inventors: Min-Hsun HSIEH, Hsinchu (TW); Ming-Chi HSU, Hsinchu (TW); Hung-Chih YANG, Hsinchu (TW)

(21) Appl. No.: 13/968,659

(22) Filed: Aug. 16, 2013

Related U.S. Application Data
(63) Continuation-in-part of application No. PCT/CN2011/071105, filed on Feb. 18, 2011.

(51) Int. Cl. H01L 33/58

(52) U.S. Cl. CPC H01L 33/58
USPC 257/98; 438/29

(57) ABSTRACT

An optoelectronic device comprising: a substrate; and a transition stack formed on the substrate comprising one first transition layer formed on the substrate having a first hollow component formed inside the first transition layer and a second transition layer formed on the first transition layer having a second hollow component formed inside the second transition layer wherein the first hollow component and the second hollow component having a volume respectively, and the volume of the first hollow component is different with the second hollow component and the material of the transition stack comprises at least two element.

### RELATED APPLICATION

This application is a continuation-in-part of PCT patent application, Ser. No. PCT/CN/2011/071105, entitled “OPTOELECTRONIC DEVICE AND METHOD FOR MANUFACTURING THE SAME”, filed Feb. 18, 2011; the contents of which are incorporated herein by reference in its entirety.

### BACKGROUND

1. Technical Field

The present disclosure relates to an optoelectronic device having a transition stack formed between the semiconductor layer and the substrate.

2. Description of the Related Art

The light radiation theory of light emitting diode (LED) is to generate light when electrons and holes recombine in the active region between the n-type semiconductor and the p-type semiconductor. Because the light radiation theory of LED is different from the incandescent light which heats the filament, the LED is called a “cold” light source.

Moreover, the LED is more sustainable, longevous, light and handy, and less power consumption, therefore it is considered as a new light source for the illumination markets. The LED applies to various applications like the traffic signal, backlight module, street light, and medical instruments, and is gradually replacing the traditional lighting sources.

### SUMMARY OF THE DISCLOSURE

An optoelectronic device comprising: a substrate; and a transition stack formed on the substrate comprising one first transition layer formed on the substrate having a first hollow component formed inside the first transition layer and a second transition layer formed on the first transition layer having a second hollow component formed inside the second transition layer wherein the first hollow component and the second hollow component having a volume respectively, and the volume of the first hollow component is different with the second hollow component and the material of the transition stack comprises at least two element.

### BRIEF DESCRIPTION OF DRAWINGS

The accompanying drawings are included to provide easy understanding of the application, and are incorporated herein and constitute a part of this specification. The drawings illustrate embodiments of the application and, together with the description, serve to illustrate the principles of the application.

FIGS. 1A-1B illustrate the theory of an optoelectronic device of the embodiment in the present disclosure;

FIGS. 2A-2F illustrate a process flow of a method of fabricating an optoelectronic device of the embodiment in the present disclosure;

FIGS. 3A-3C illustrate the structure of the optoelectronic device of the embodiment in the present disclosure; and

FIGS. 4A-5B illustrate scanning electron microscope (SEM) pictures of the embodiment in the present disclosure.

FIGS. 6A-6C illustrate an LED module of an embodiment in the present disclosure.

FIGS. 7A-7B illustrate a lighting apparatus of an embodiment in the present application form different perspectives.

FIG. 8 is an explosive diagram of a bulb in accordance with an embodiment of the present application.

### DETAILED DESCRIPTION OF THE PREFERRED EMBODIMENTS

Reference is made in detail to the preferred embodiments of the present application, examples of which are illustrated in the accompanying drawings. Wherever possible, the same reference numbers are used in the drawings and the description to refer to the same or like parts.

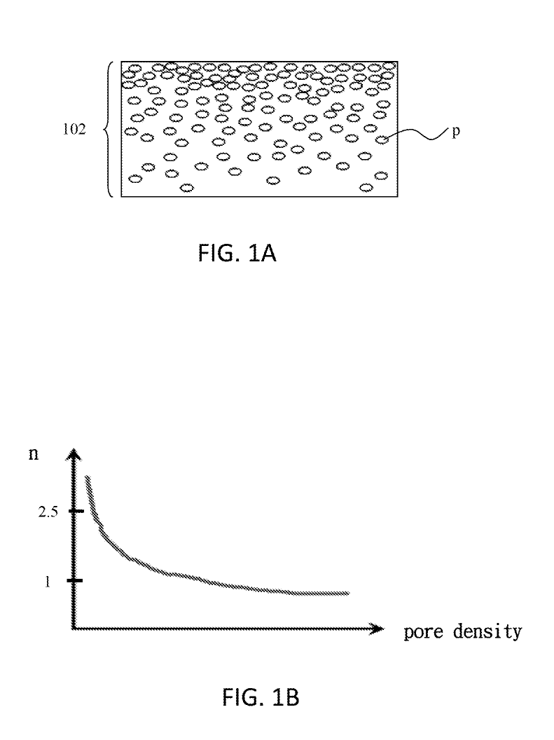

The present disclosure describes an optoelectronic device and a method of fabricating the optoelectronic device. In order to have a thorough understanding of the present disclosure, please refer to the following description and the illustrations of FIG. 1 to FIG. 8.

When light transmitting from the medium with higher refractive index into the medium with lower refractive index, the light extraction efficiency is decreasing because of the difference in refractive index. In this application, we provide a transition stack with gradual refractive index to increase light extraction efficiency. FIGS. 1A-1B illustrate a transition stack with voids of the embodiment in the present disclosure. As shown in FIG. 1A, a plurality of the voids p is formed inside the transition stack 102. By adjusting the volume or density of the voids p in the transition stack 102, the light extraction efficiency is dramatically increased. The refractive index (n) can be adjusted by the following formula: n(z)=1*m+2.4*(1−m) wherein element z is the crystal growth direction of the transition stack, and the element m is the density of the voids. FIG. 1B illustrates the diagram of the density of the voids to the refractive index of the transition stack. For example, when the material of the transition stack 102 is GaN, by adjusting the density of the voids of the transition stack 102, the refractive index of the transition stack 102 can be changed from n=2.5 to n=1˜1.9.

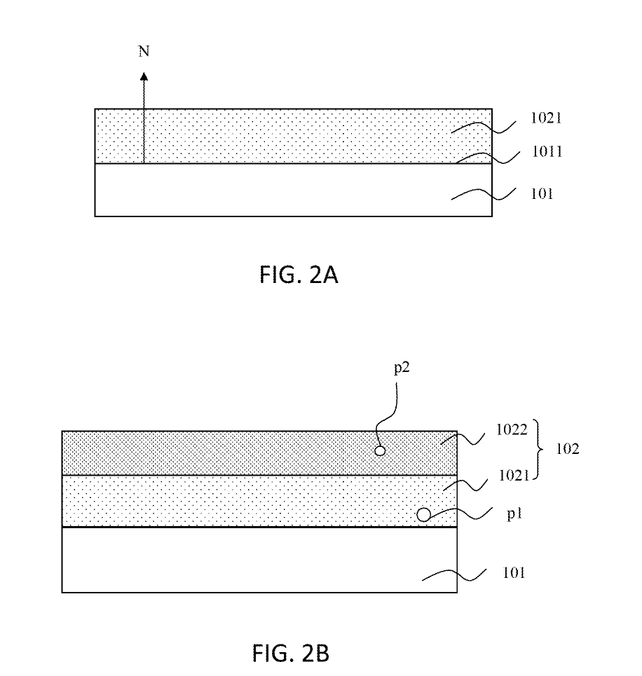

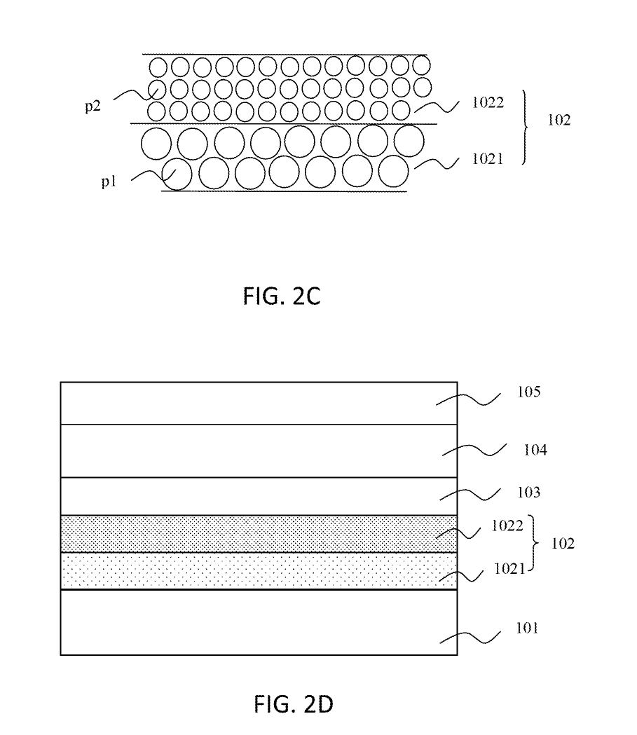

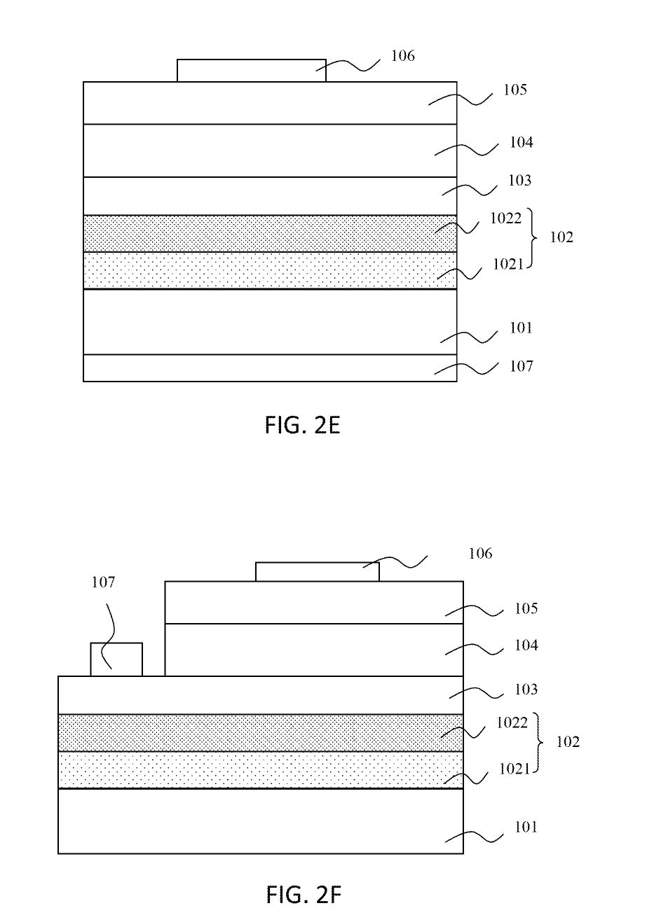

By the theory illustrated above, FIGS. 2A to 2F illustrate a process flow of the method of fabricating the optoelectronic device of first embodiment of the present disclosure. FIGS. 2A-2B illustrates a substrate 101 having a normal line direction N and a first major surface 1011. A first transition layer 1021 is formed on the first surface 1011 of the substrate 101.

FIG. 2B illustrates a second transition layer 1022 formed on the first transition layer 1021 wherein the first transition layer 1021 and the second transition layer 1022 can be a transition stack 102.

Following, the transition stack 102 can be etched by the following method to form at least one first hollow component p1 in the first transition layer 1021 and at least one second hollow component p2 in the second transition layer 1022. The first hollow component p1 and the second hollow component p2 can be pore, void, bore, pinhole, cavity, or at least two first hollow components p1 or at least two second hollow components p1 that can link into a mesh or porous structure. The forming methods as also described in TW application No. TW099132135, TW099137445, and TW099142035 and also assigned to the present assignee are incorporated herein by reference in their entireties.

The methods include: 1) Wet etching with an aqueous solution of at least one of H₂SO₄, H₃PO₄, H₂C₂O₄, HCl, KOH, and NaOH, ethylene glycol solution or their mixture;

2) Electrochemical etching with an aqueous solution of at least one of H₂SO₄, H₃PO₄, H₂C₂O₄, HCl, KOH, and NaOH, an ethylene glycol solution or their mixture;

3) Lateral electrochemical etching with an aqueous solution of at least one of H₂SO₄, H₃PO₄, H₂C₂O₄, HCl, KOH, and NaOH, an ethylene glycol solution or their mixture; or

4) Dry etching such as inductive coupling plasma (ICP), reactive ion etch (RIE) by a gas containing at least one of HCl, Cl₂, SF₆, H_{2,} BCl₃ and CH₄.

In this embodiment, the width of the first hollow component p1 and the second hollow component p2 are defined as the largest size of the first hollow component p1 and the second hollow component p2 perpendicular with the normal line direction N of the substrate 101. In one embodiment, the width of the first hollow component p1 and the second hollow component p2 are different. In another embodiment, the width of the first hollow component p1 is larger than the width of the second hollow component p2.

In this embodiment, the density of the first hollow component p1 and density of the second hollow component p2 are different. In another embodiment, the density of the first hollow component p1 is larger than the density of the second hollow component p2.

In this embodiment, the material of the transition stack 102 contains one element selected from the group consisting of Al, Ga, In, As, P, and N, such as GaN or AlGaInP.

In one embodiment, the first hollow component p1 and the second hollow component p2 can be pore, void, bore, pinhole, cavity, and the width of the first hollow component p1 or the second hollow component p2 can be 10 nm-2000 nm, 100 nm-2000 nm, 300 nm-2000 nm, 500 nm-2000 nm, 800 nm-2000 nm, 1000 nm-2000 nm, 1300 nm-2000 nm, 1500 nm-2000 nm, or 1800 nm-2000 nm. In one embodiment, the width W of the hollow component p1 close to the substrate is larger than the width of the hollow component p1 close to the second transition layer 1022.

In another embodiment, the first hollow components p1 or the second hollow components p2 can be multiple voids or porous structure. The average width of the plurality of the first hollow components p1 or the second hollow components p2 can be 10 nm-2000 nm, 100 nm-2000 nm, 300 nm-2000 nm, 500 nm-2000 nm, 800 nm-2000 nm, 1000 nm-2000 nm, 1300 nm-2000 nm, 1500 nm-2000 nm, or 1800 nm-2000 nm. In another embodiment, the average distance D of the plurality of the first hollow components p1 or the second hollow components p2 can be 10 nm-2000 nm, 100 nm-2000 nm, 300 nm-2000 nm, 500 nm-2000 nm, 800 nm-2000 nm, 1000 nm-2000 nm, 1300 nm-2000 nm, 1500 nm-2000 nm, or 1800 nm-2000 nm.

The porosity Φ of the plurality of the first hollow components p1 or the second hollow components p2 can be defined as the total volume of the first hollow component (or second hollow component) Vᵥ divided by the overall volume V_{T} of the first transition layer 1021 (or second transition layer 1022)

$$( φ = \frac{{V}_{V}}{{V}_{T}} ) .$$

In one embodiment, the porosity Φ of the plurality of the first hollow components p1 or the second hollow components p2 can be 5%-90%, 10%-90%, 20%-90%, 30%-90%, 40%-90%, 50%-90%, 60%-90%, 70%-90% or 80%-90%.

Following, FIG. 2C illustrates another embodiment which discloses the plurality of first hollow components p1 can be a regular array structure. For example, the plurality of first hollow components p1 has the same size and forms a first photonic crystal structure. The plurality of second hollow components p2 can also be a regular array structure. For example, the plurality of second hollow components p2 has the same size and forms a second photonic crystal structure. In this embodiment, the stress can be released and the reflection and scattering of light can be enhanced by the first photonic crystal structure and the second photonic crystal structure. In another embodiment, the width of the plurality of the first hollow components p1 and the plurality of the second hollow components p2 are different. In another embodiment, the width of the plurality of the first hollow components p1 is larger than the width of the plurality of the second hollow components p2.

Following, FIG. 2D illustrates a first conductivity-type semiconductor layer 103, an active layer 104, and a second conductivity-type semiconductor layer 105 are formed on the second transition layer 1022 subsequently.

Finally, FIG. 2E illustrates, two electrodes 106, 107 are formed on the second conductivity-type semiconductor layer 105 and the substrate 101 respectively to form a vertical type optoelectronic device 100.

In one embodiment, as FIG. 2F illustrates, partial of the active layer 104 and the second conductivity-type semiconductor layer 105 are etched to expose partial of the first conductivity-type semiconductor layer 103. Two electrodes 106, 107 are formed on the second conductivity-type semiconductor layer 105 and the first conductivity-type semiconductor layer 103 respectively to form a horizontal type optoelectronic device 100′. The material of the electrodes 106, 107 can be Cr, Ti, Ni, Pt, Cu, Au, Al or Ag.

In one embodiment, the optoelectronic device 100′ can be bonded on a submount to form a flip-chip structure.

The plurality of the first hollow components p1 or the second hollow components p2 inside the first transition layer 1021 or the second transition layer 1022 are empty spaces or cavities having a refractive index and can act as an air lens. Because of the difference of the refractive index of the plurality of the first hollow components p1 or the second hollow components p2 and the semiconductor layer, for example, the refractive index of the semiconductor layer is 2-3, and the refractive index of air is 1 so the light transmitting into the plurality of first hollow components p1 or the second hollow components p2 change its emitting direction to outside the optoelectronic device 100 and increases the light emitting efficiency. Besides, the plurality of the first hollow components p1 or the second hollow components p2 can be a scattering center to change the direction of the photon and decrease the total reflection. By increasing the porosity of the first hollow components p1 or the second hollow components p2, the effect mentioned above is increased. Besides, in another embodiment, because the width of the first hollow component p1 is larger than the width of the second hollow component p2, the following epitaxial growth becomes easier and the epitaxial quality is improved.

In another embodiment, the transition stack 102 can be an n-type doped layer, and the first hollow component p1 and the second hollow component p2 are formed by electrochemical etching. Because the volume or the density of the hollow components in the transition stacks 102 formed by electrochemical etching is related to the doping concentration, with the same electrochemical etching condition, the lower the doping concentration of the transition stacks 102, the smaller volume or the lower density of the hollow components in the transition stacks 102. Therefore, by adjusting the doping concentration of the first transition layer 1021 and the second transition layer 1022 in the transition stacks 102, the first hollow component p1 and the second hollow component p2 with different volume and density are formed. In one embodiment, the doping concentration of the transition stacks 102 can be 1E15-1E19 cm⁻³, 1E16-1E19 cm⁻³, 1E17-1E19 cm⁻³, 1E18-1E19 cm⁻³, 5×1E18-1E19 cm⁻³, 5×1E17-1E19 cm⁻³, or 5×1E17-1E18 cm⁻³.

In another embodiment, a connecting layer (not shown) is formed on the second transition layer 1022 wherein the connecting layer is an unintentional doped layer or an undoped layer. The forming temperature of the connecting layer can be 800-1200° C., and the pressure can be 100-700 mbar, wherein the adjustment is based on the porosity and volume of the hollow component of the transition stack 102 to coalesce by lateral growth so the width or the density of the hollow component closer to the interface of the transition stack 102 and the connecting layer is decreased, and the connecting layer can be formed consecutively.

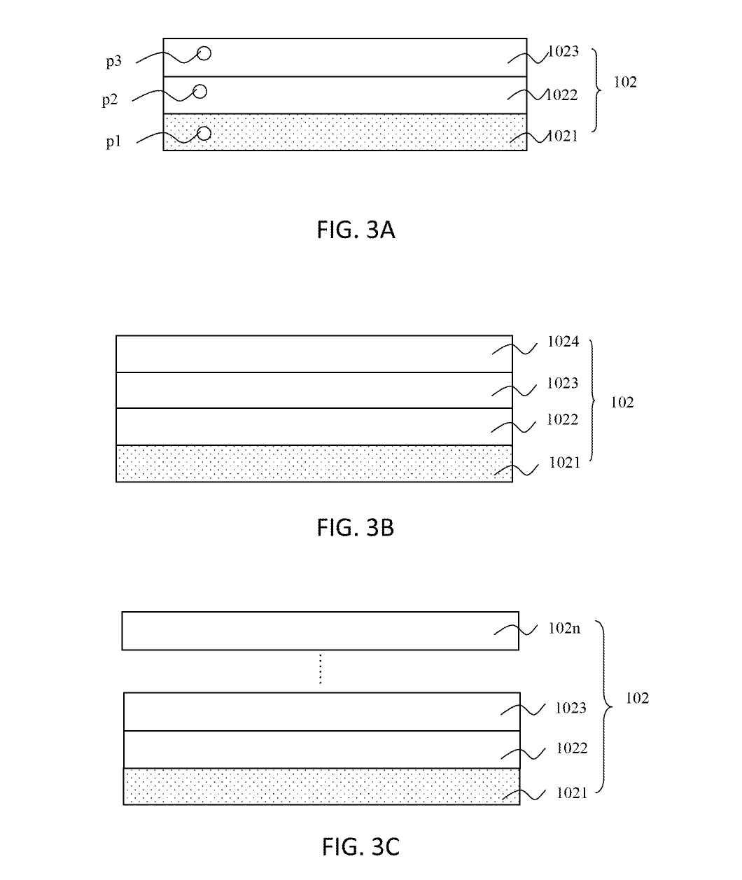

FIGS. 3A-3C illustrate a process flow of a method of fabricating an optoelectronic device of another embodiment in the present disclosure. FIGS. 3A-3B illustrate the transition stack 102 further including a third transition layer 1023 and/or a fourth transition layer 1024. FIG. 3C illustrates the transition stack 102 can include n layers of transition layers 1021˜102n to increase the light extraction efficiency and release the stress according to the actual design of the optoelectronic device 100. In the embodiment, each transition layer in the transition stack 102 can have at least one hollow component such as pore, void, bore, pinhole, cavity, or at least two hollow components that can link into a mesh or porous structure. The fabricating method, material, size or other character is the same with the embodiment mentioned above.

FIG. 3A illustrates that at least one first hollow component p1 is formed in the first transition layer 1021, at least one second hollow component p2 is formed in the second transition layer 1022 and at least one third hollow component p3 is formed in the third transition layer 1023. In one embodiment, the volume of the first hollow component p1, the second hollow component p2 and the third hollow component p3 can be the same or different. In another embodiment, the volume, width and/or the density of the first hollow component p1, the second hollow component p2 and the third hollow component p3 can be p1>p2>p3. In another embodiment, the volume, width and/or the density of the first hollow component p1, the second hollow component p2 and the third hollow component p3 can be p1>p2 and p3>p2. In another embodiment, the volume, width and/or the density of the first hollow component p1, the second hollow component p2 and the third hollow component p3 can be p1<p2, p3<p2.

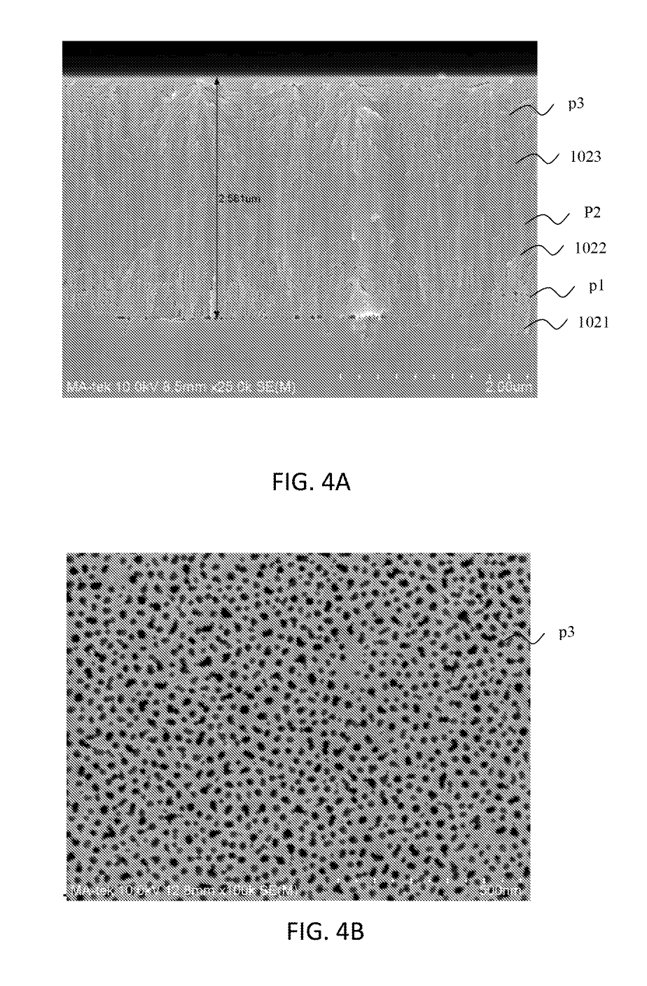

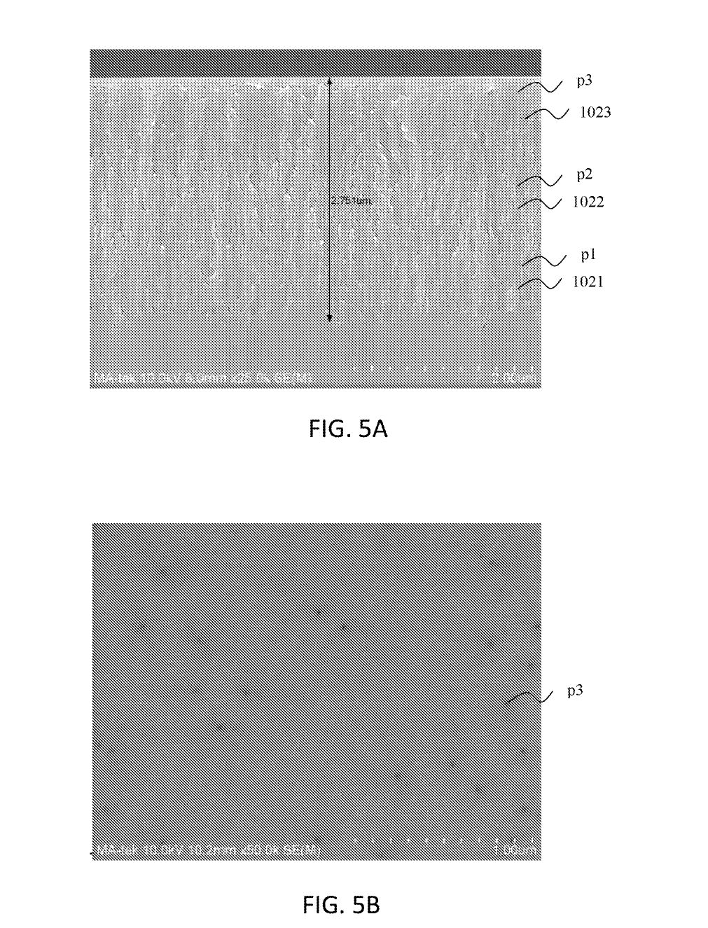

FIGS. 4A-5B illustrate scanning electron microscope (SEM) pictures of the transition stack 102 of the embodiment of the present disclosure. FIG. 4A illustrates a transition stack 102 includes a first transition layer 1021, a second transition layer 1022 and a third transition layer 1023 and the width or the density of the second hollow component p2 is smaller than the width or the density of the first hollow component p1 and third hollow component p3. FIG. 4B illustrates the top view of the transition stack 102. The average distance of the plurality of the third hollow components p3 in the third transition layer 1023 is 20-100 nm. In this embodiment, by adjusting the width or the density of the first hollow component p1, the second hollow component p2 and the third hollow component p3, the refraction index of the transition stack 102 can be changed, and the transition stack 102 can be used as a DBR (distributed Bragg reflector).

FIGS. 5A-5B illustrate scanning electron microscope (SEM) pictures of the transition stack 102 of another embodiment of the present disclosure. FIG. 5A illustrates a transition stack 102 includes a first transition layer 1021, a second transition layer 1022 and a third transition layer 1023 and the width or the density of the second hollow component p2 is larger than the width or the density of the first hollow component p1 and third hollow component p3. FIG. 5B illustrates the top view of the transition stack 102. The average distance of the plurality of the third hollow components p3 in the third transition layer 1023 is 20-100 nm. In this embodiment, by adjusting the width or the density of the first hollow component p1, the second hollow component p2 and the third hollow component p3, the refraction index of the transition stack 102 can be changed, and the transition stack 102 can be used as a DBR (distributed Bragg reflector).

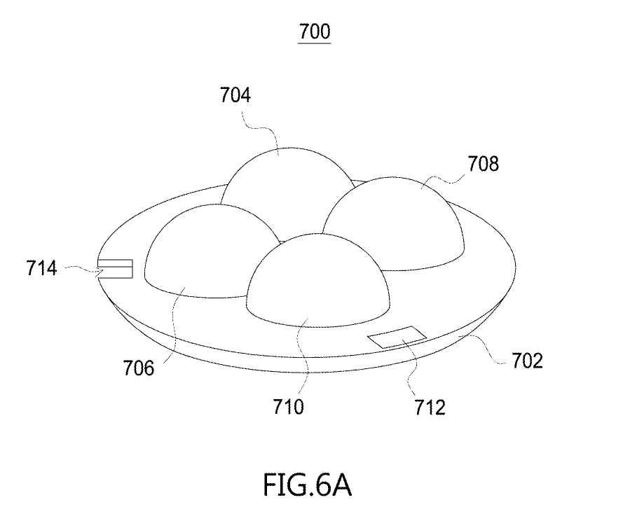

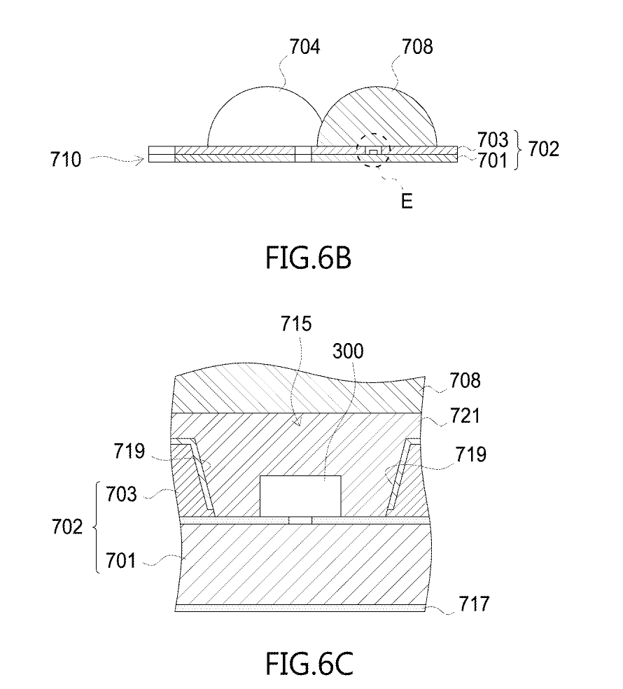

FIGS. 6A-6C illustrates an LED module of an application in the present disclosure. FIG. 6A is an external perspective view illustrating an optoelectronic device module 700 including a submount 702, an optoelectronic device (not shown) described above, a plurality of lens 704, 706, 708, 710, and two power supply terminals 712, 714. The LED module 700 is attached to a lighting unit 800 (mentioned later).

FIG. 6B is a plan view illustrating the optoelectronic device module 700, and FIG. 6C is an enlarged view illustrating a portion E shown in FIG. 6B. As FIG. 6B shows, the submount 702 including an upper subunit 703 and a lower subunit 701, and at least one surface of the lower subunit 701 is contacted with the upper subunit 703. The lens 704, 708 are formed on the upper subunit 703. At least one through hole 715 is formed on the upper subunit 703 and at least one of the optoelectronic device 300 is formed inside the through hole 715 and contacted with the lower subunit 701. Besides, the optoelectronic device 300 is encapsulated by an encapsulating material 721 wherein the material of the encapsulating material 721 may be a silicone resin, an epoxy resin or the like. And a lens 708 is optionally formed on the encapsulating material 721. In one embodiment, a reflecting layer 719 is formed on the sidewall of the through hole 715 to increase the light emitting efficiency. A metal layer 717 can be formed on the lower surface of the lower subunit 701 for improving heat dissipation.

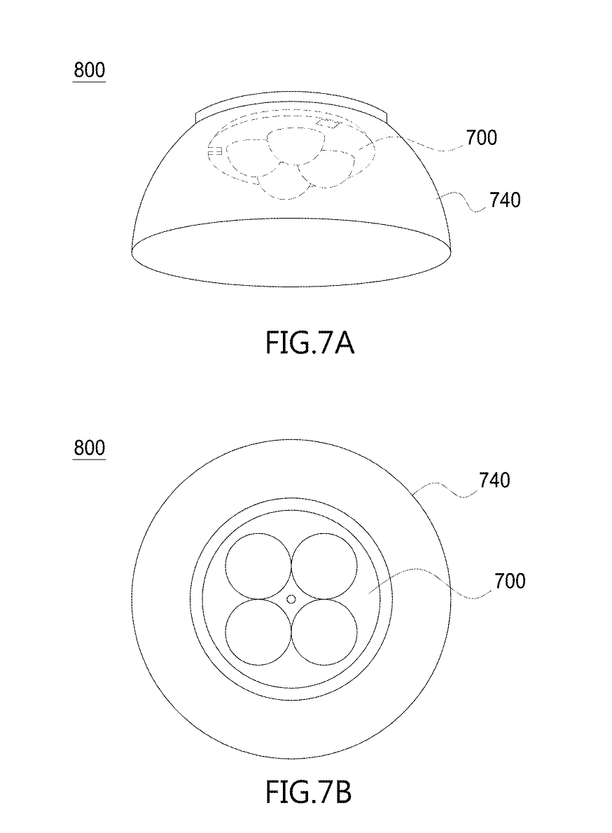

FIGS. 7A-7B illustrate a lighting apparatus of an embodiment in the present application form different perspectives. The lighting apparatus 800 includes an optoelectronic device module 700, a case 740, a power supply circuit (not shown) to supply current to the lighting apparatus 800 and a control unit (not shown) to control the power supply circuit. The lighting apparatus 800 can be an illumination device, such as street lamps, headlights or indoor illumination light source, and can be a traffic sign or a backlight module of the display panel.

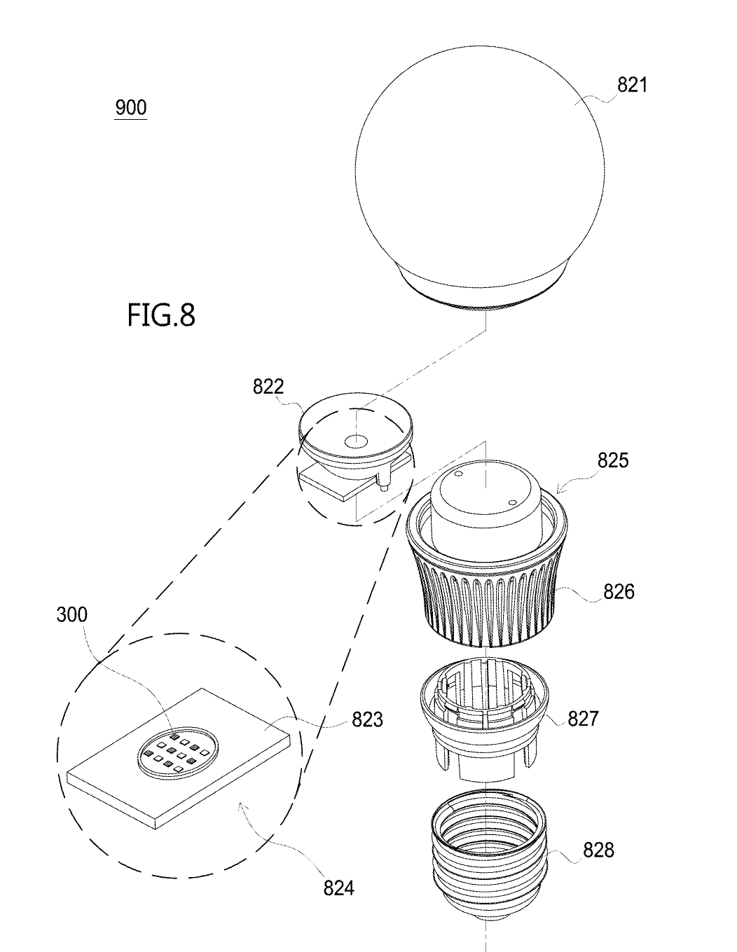

FIG. 8 shows an explosive diagram of a bulb in accordance with another application of the present application. The bulb 900 comprises a cover 821, a lens 822, a lighting module 824, a lamp holder 825, a heat sink 826, a connecting part 827, and an electrical connector 828. The lighting module 824 comprises a carrier 823 and a plurality of optoelectronic device 300 of any one of the above mentioned embodiments on the carrier 823.

Specifically, the optoelectronic device 100 comprises light-emitting diode (LED), photodiode, photo resister, laser diode, infrared emitter, organic light-emitting diode and solar cell. The substrate 101 can be a growing or carrying base. The material of the substrate 101 comprises an electrically conductive substrate, electrically insulating substrate, transparent substrate, or opaque substrate. The material of the electrically conductive substrate can be metal such as Ge and GaAs, oxide such as LiAlO₂ and ZnO, nitrogen compound such as GaN and AlN, phosphide such as InP, silicon compound such as SiC, or Si. The material of the transparent substrate can be chosen from sapphire (Al₂O₃), LiAlO₂, ZnO, GaN, AlN, glass, diamond, CVD diamond, diamond-like carbon (DLC), spinel (MgAl₂O₃), SiOₓ, or LiGaO₂.

The first semiconductor layer 103 and the second semiconductor layer 105 are different in electricity, polarity or dopant, or are the different semiconductor materials used for providing electrons and holes, wherein the semiconductor material can be single semiconductor material layer or multiple semiconductor material layers. The polarity can be chosen from any two of p-type, n-type and i-type. The active layer 102 is disposed between the first semiconductor layer 103 and the second semiconductor layer 105 respectively where the electrical energy and the light energy can be converted or stimulated converted. The devices which can convert or stimulated convert the electrical energy into the light energy can be light-emitting diode, liquid crystal display, and organic light-emitting diode. The devices which can convert or be stimulatively converted the light energy into the electrical energy can be solar cell and optoelectronic diode. The material of the first semiconductor layer 103 the active layer 104 and the second semiconductor layer 105 comprises Ga, Al, In, As, P, N, Si, and the combination thereof such as aluminum gallium indium phosphide (AlGaInP) series material, aluminum gallium indium nitride (AlGaInN) series material and so on.

The optoelectronic device of another embodiment in the application is a light-emitting diode, of which the light spectrum can be adjusted by changing the essentially physical or chemical factor of the single semiconductor material layer or the multiple semiconductor material layers. The material of the single semiconductor material layer or the multiple semiconductor material layers can contain elements selected from Al, Ga, In, P, N, Zn, O, or the combination thereof such as aluminum gallium indium phosphide (AlGaInP) series material, aluminum gallium indium nitride (AlGaInN) series material and so on. The structure of the active layer 103 can be single heterostructure (SH), double heterostructure (DH), double-side double heterostructure (DDH) or multi-quantum well (MQW), wherein the wavelength of the light emitted from the active layer 103 can be changed by adjusting the number of the pairs of MQW.

In one embodiment of the application, a buffer layer (not shown) can be selectively disposed between the first semiconductor layer 103 and the transition stack 102, or between the transition stack 102 and the substrate 101. The buffer layer is between the two material systems to transit the material system of the substrate 101 to the material system of the first semiconductor layer 103. For the structure of the light-emitting diode, the buffer layer is used to reduce the crystal mismatch between two materials. On the other hand, the buffer layer comprises a single layer, multiple layers or a structure which comprises two materials or two separated structures. The material of the buffer layer can be selected from organic material, inorganic material, metal or semiconductor material. The structure of the buffer layer can be a reflector layer, a thermally conductive layer, an electrically conductive layer, an ohmic contact layer, an anti-deformation layer, a stress release layer, a bonding layer, a wavelength conversion layer or a mechanically fixing structure. In one embodiment, the material of the buffer layer can be AlN or GaN, and the buffer layer can be formed by sputtering or atomic layer deposition (ALD).

A contacting layer (not shown) can be selectively formed on the second semiconductor layer 105. The contacting layer is disposed on the side of the second semiconductor layer 105 away from the active layer 104. Specifically, the contacting layer can be optical layer, electrical layer, or the combination thereof. The optical layer can change the radiation or the light from or entering the active layer 104, wherein the optical layer can change but not limited to the frequency, the wavelength, the intensity, the flux, the efficiency, the color temperature, rendering index, light field, angle of view. The electrical layer can change the value, density, distribution of voltage, resistor, current and capacitance of any two relative sides of the contacting layer. The material of the contacting layer comprises oxide such as conductive oxide, transparent oxide and the oxide with the transparency over 50%, metal such as transparent metal and the metal with transparency over 50%, organic material, inorganic material, fluoresce material, ceramic, semiconductor material and doping semiconductor material. In some applications, the material of the contacting layer can be selected from InTiO, CdSnO, SbSnO, InZnO, ZnAlO or ZnSnO. If the material of the contacting layer is transparent metal, the thickness of the contacting layer is in a range of 0.005 μm ˜0.6 μm.

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

Although the drawings and the illustrations above are corresponding to the specific embodiments individually, the element, the practicing method, the designing principle, and the technical theory can be referred, exchanged, incorporated, collocated, coordinated except they are conflicted, incompatible, or hard to be put into practice together.

Although the present application has been explained above, it is not the limitation of the range, the sequence in practice, the material in practice, or the method in practice. Any modification or decoration for present application is not detached from the spirit and the range of such.

What is claimed is:

1. An optoelectronic device comprising:
a substrate; and
a transition stack formed on the substrate comprising one first transition layer formed on the substrate having a first hollow component formed inside the first transition layer and a second transition layer formed on the first transition layer having a second hollow component formed inside the second transition layer wherein the first hollow component and the second hollow component having a volume respectively, and the volume of the first hollow component is different with the second hollow component and the material of the transition stack comprises at least two element.

2. The optoelectronic device of claim 1, wherein more than one of the first hollow component are formed inside the first transition stack and wherein more than one of the second hollow component are formed inside the second transition stack and at least two first hollow components and/or at least two second hollow components form a mesh structure, a porous structure, or a regular array wherein the average distance of the first hollow components and/or the second hollow components can be 10 nm-2000 nm and the porosity of the hollow components can be 5-90%.

3. The optoelectronic device of claim 2, wherein the density of the first hollow components and the density of the second hollow components is different.

4. The optoelectronic device of claim 1, further comprising a first conductivity-type semiconductor layer, an active layer and a second conductivity-type semiconductor layer formed on the transition stack.

5. The optoelectronic device of claim 4, wherein the material of the transition stack, the first conductivity-type semiconductor layer, the active layer and the second conductivity-type semiconductor layer contains at least one element selected from the group consisting of Al, Ga, In, As, P, and N.

6. The optoelectronic device of claim 3, wherein the volume, width and/or the density of the first hollow components is larger than the volume, width and/or the density of the second hollow components.

7. The optoelectronic device of claim 1, wherein the transition stack is an n-type doped layer with the doping concentration of 1E15-1E19 cm⁻³ and/or the doping concentration of the first transition layer is different with the doping concentration of the second transition layer.

8. The optoelectronic device of claim 2, wherein first hollow components and the second hollow components are photonic crystal structure.

9. The optoelectronic device of claim 1, further comprising a connecting layer formed on the transition stack, and the connecting layer is an unintentional doped layer or an undoped layer.

10. The optoelectronic device of claim 1, wherein the transition stack further comprising a third transition layer formed on the second transition layer having a third hollow component formed inside the third transition layer wherein the third hollow component having a volume, and the volume of the third hollow component is different with the first hollow component and the second hollow component.

11. A method of fabricating an optoelectronic device comprising:
providing a substrate;
forming a first transition layer on the substrate;
forming one first hollow component inside the first transition layer;
forming a second transition layer on the first transition layer; and
forming one second hollow component inside the second transition layer wherein the first hollow component and the second hollow component having a volume respectively, and the volume of the first hollow component is different with the second hollow component and the material of the transition stack comprises at least two element.

12. The method of fabricating an optoelectronic device of claim 11, wherein the first hollow component and the second hollow component is formed by wet etching, electrochemical etching, lateral electrochemical etching or dry etching.

13. The method of fabricating an optoelectronic device of claim 11, wherein more than one of the first hollow component are formed inside the first transition stack and wherein more than one of the second hollow component are formed inside the second transition stack and at least two first hollow components and/or at least two second hollow components form a mesh structure, a porous structure, or a regular array wherein the average distance of the first hollow components and/or the second hollow components can be 10 nm-2000 nm and the porosity of the hollow components can be 5-90%.

14. The method of fabricating an optoelectronic device of claim 12, wherein the density of the first hollow components and the density of the second hollow components are different.

15. The method of fabricating an optoelectronic device of claim 11, further comprising a first conductivity-type semiconductor layer, an active layer and a second conductivity-type semiconductor layer formed on the transition stack and the material of the transition stack, the first conductivity-type semiconductor layer, the active layer and the second conductivity-type semiconductor layer contains one element selected from the group consisting of Al, Ga, In, As, P, and N.

16. The method of fabricating an optoelectronic device of claim 14, wherein the volume, width and/or the density of the first hollow components is larger than the volume, width and/or the density of the second hollow components.

17. The method of fabricating an optoelectronic device of claim 11, wherein the first hollow component and the second component are formed by electrochemical etching and the transition stack is an n-type doped layer with the doping concentration of 1E15-1E19 cm⁻³ and/or the doping concentration of the first transition layer is different with the doping concentration of the second transition layer.

18. The method of fabricating an optoelectronic device of claim 13, wherein first hollow components and the second hollow components are photonic crystal structure.

19. The method of fabricating an optoelectronic device of claim 11, further comprising a connecting layer formed on the transition stack, and the connecting layer is an unintentional doped layer or an undoped layer.

20. The method of fabricating an optoelectronic device of claim 11, wherein the transition stack further comprising a third transition layer formed on the second transition layer having a third hollow component formed inside the third transition layer wherein the third hollow component having a volume, and the volume of the third hollow component is different with the first hollow component and the second hollow component.
